(19) United States
(12) Patent Application Publication
(10) Pub. No.: US 2004/0130007 A1
(43) Pub. Date: Jul. 8, 2004

(54) Flat lead package for a semiconductor device

(76) Inventors: Cheng-Ho Hsu, Kaohsiung (TW); Yi-Hua Chang, Feng-Shan City (TW); Jen-Cheng Liou, Kaohsiung (TW)

Correspondence Address: Rabin & Berdo, P.C., Suite 500, 1101 14th Street, Washington, DC, 20005, US

(21) Appl. No.: 10/336,739

(22) Filed: Jan. 6, 2003

(51) Int. Cl. H01L 23/495

(52) U.S. Cl. 257/666

(57) ABSTRACT

A lead semiconductor package includes a leadframe, a chip and an encapsulant. The leadframe has a central opening and multiple flat leads. The multiple flat leads define edges of the central opening. Each lead has an exposed portion and an inner thin portion. The inner thin portion is close to the central opening. The chip is mounted on the leads and is wire bonded to the inner thin portion. The inner thin portion is thicker than the exposed thick portion to provide a wire bonding space. Therefore, the semiconductor package is very thin. Further, the encapsulant covers the leadframe except portions of the leads and a portion of the chip to increase heat radiation.

### BACKGROUND OF THE INVENTION

1. Field of the Invention

The present invention relates to a flat lead package for a semiconductor device, and more specifically to a semiconductor device packaged with flat leads in a low-profile package and using a simple packaging procedure.

2. Description of Related Art

With reference to FIG. 4, a conventional lead semiconductor package can be surface mounted on a PCB (not shown). The lead package includes a bent leadframe (40), a chip (50), a two-sided adhesive (51) and encapsulant (60). The bent leadframe (40) has a central opening (42) and multiple leads (41) to define edges of the central opening (42). Each lead (41) has a low flat portion (411) and a high flat portion (412). Each low flat portion (411) and each high flat portion (412) has a top face (not numbered) and a bottom face (not numbered). The two-sided adhesive (52) is bonded the top face of each high flat portion (412). The chip (50) is mounted upside down and has a top face (501) with a center, a bottom face (502) and an I/O pad (not shown) on the center of the top face (501). The chip is bonded to the two-sided adhesive (52) on the high flat portions (412), and the I/O pad corresponds to the central opening (42) in the leadframe (40). The I/O pad of the chip (50) is wire bonded to the high flat portions (412) of the leads (41) through the central opening (42). Encapsulant (60) is applied to the chip (50) and the leadframe (40) except the bottom face of each low flat portion (411) using a mold (not shown) to complete the lead semiconductor package. This conventional lead package utilizes the high flat portion (412) of each lead (41) to provide a wire bonding space to connect between the chip (50) and leadframe (40). The low flat portion (411) is flat and exposed from the encapsulant (60) to be surface mounted on the PCB (not shown). However, the lead semiconductor package does not dissipate heat readily because the chip (50) is sealed in encapsulant, and the lead semiconductor package cannot normally be used in a high temperature application.

With reference to FIG. 5, another conventional lead semiconductor package was developed to overcome the drawback of the previously described lead semiconductor package. The improved lead semiconductor package further includes a die pad (70) having an outer face (71) and an inner face (72). The inner face (72) is attached to the bottom face (502) of the chip (50). The encapsulant (60) does not cover the outer face (72) of the die pad (70). Therefore, heat from the chip (50) can be dissipated from the outer face (71) of the die pad (70).

The two conventional lead semiconductor packages are thin because of the inner bent leadframe and inner wire bonding process. The low flat portions of the leads are attached to a PCB and also can radiate some heat from the chip. However, the two lead semiconductor packages still have the following drawbacks.

1. A mold is required to fabricate the bent leadframe so cost for fabricating the lead semiconductor package increases. In addition, the bent leadframe is very thin and is made of metal so the bent leadframe is easily deformed.

2. The high flat portion of the bent leadframe keeps the forgoing semiconductor packages from being thinner.

Therefore, the present invention provides a new lead semiconductor package to mitigate or obviate the aforementioned problems.

### SUMMARY OF THE INVENTION

An objective of the present invention is to provide a low-profile lead semiconductor package by using a completely flat leadframe to package a chip.

Another objective of the present invention is to reduce packaging cost for the lead semiconductor package.

Another objective of the present invention is to provide a lead semiconductor package for transmitting electronic signals well.

Other objectives, advantages and novel features of the invention will become more apparent from the following detailed description when taken in conjunction with the accompanying drawings.

### BRIEF DESCRIPTION OF THE DRAWINGS

FIG. 1 is a side plan view of a first embodiment of a lead semiconductor package in accordance with the present invention;

FIG. 2 is a side plan view of a second embodiment of a lead semiconductor package in accordance with the present invention;

FIG. 3A is a bottom plan view of the lead semiconductor package in the FIG. 1 with a dual-line leadframe;

FIG. 3B is a bottom plan view of the lead semiconductor package in the FIG. 1 with a quad-line leadframe;

FIG. 4 is a side plan view of a conventional lead semiconductor package in accordance with the prior art; and

FIG. 5 is a side plan view of another conventional lead semiconductor package in accordance with the prior art.

### DETAILED DESCRIPTION OF THE PREFERRED EMBODIMENT

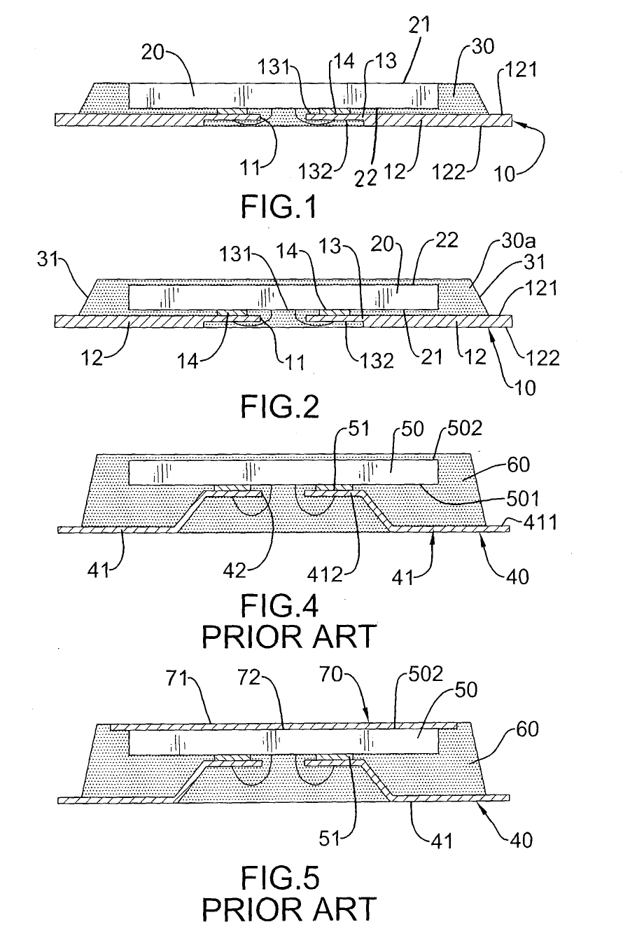

With reference to FIG. 1, a first preferred embodiment of a lead semiconductor package includes a completely flat leadframe (10), a chip (20) and encapsulant (30).

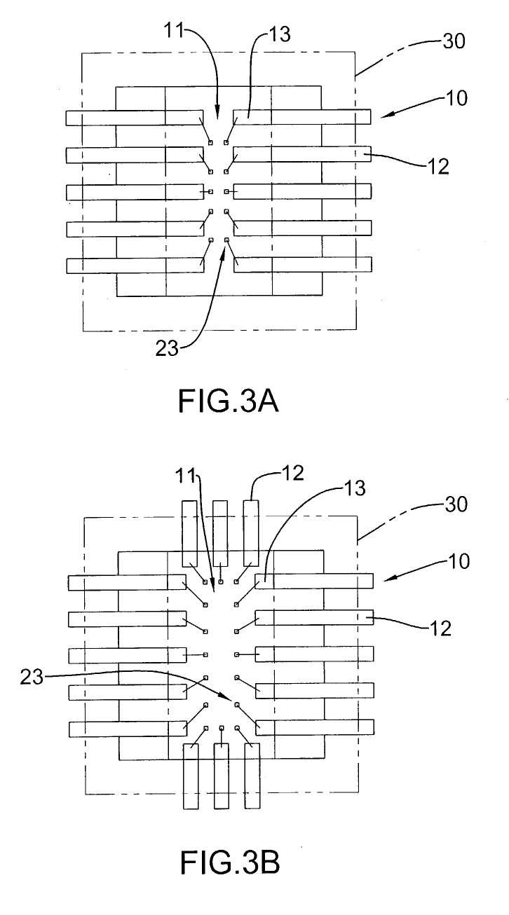

With further reference to FIG. 3A, the completely flat leadframe (10) has a central opening (11) with two opposite edges (not numbered) and multiple flat leads (not numbered). Two edges of the central opening (11) are defined by the leads being formed in dual-lines. Each lead has an exposed thick portion (12) and an inner thin portion (13). The exposed thick portion (12) has an inner face (121) and an outer face (122) with both having a thickness. The inner thin portion (13) extends longitudinally from the exposed thick portion (12) along the inner face (121). The inner thin portion also has a top face (131) and a bottom face (132). The inner thin portion (13) is optimally greater than half as thick as the thick exposed portion (12). Further, with reference to FIG. 3B, the leads can also be deposed in quad-lines to define four edges of the central opening (11).

With reference to FIGS. 1 and 3A, the chip (20) has a top surface (21) and a bottom surface (22), and an I/O pad (23) on the top surface (21). The top surface (21) of the chip (20) faces down, and the I/O pad (23) is aligned with the central opening (11) of the leadframe (10). Then the top surface (21) is attached to the top faces (131) of the inner thin portions (13) of the leads by a two-sided adhesive (14). The I/O pad (23) faces the central opening (11). The bottom face (132) of the inner thin portion (13) is wire bonded to the I/O pad (23) through the central opening (11). The encapsulant (30) covers the chip (20) and the leadframe (10) except for the bottom surface (22) of the chip (20) and the outer face (122) of the exposed thick portion (12) of each lead.

With reference to FIG. 2, a second preferred embodiment of the lead semiconductor package in accordance with the present invention has encapsulant (30a) further covering the bottom surface (22) of the chip (20). The encapsulant (30a) has four sides (31). The exposed thick portions (12) protrude from the sides (31) or are flush with the side of the encapsulant (30a).

Further, a silver material or an alloy of Ni, Pd and Au is plated on the bottom face (132) of each inner thin portion to securely attach the wires between the chip (20) and the leads.

Based on the forgoing description, the present invention provides a lead semiconductor package with a completely flat leadframe. The lead semiconductor package has many advantages.

1. The leadframe does not require a bending procedure so packaging cost of the lead semiconductor package is lower.

2. The thickness of the lead semiconductor package is thinner because the leadframe is completely flat and a recess is formed in each lead.

3. The lead semiconductor package has a good heat dissipation capability. Most portion of each lead is exposed and the chip is also exposed through the encapsulant to radiate heat from the chip.

4. The lead semiconductor package has good quality for transmitting electric signals between the chip and the PCB. Each lead is flat so a short path is provided for the electric signal. Therefore, transmission delay is reduced.

Even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A flat lead semiconductor package comprising:
a leadframe having multiple flat leads and a central opening defined by the flat leads; wherein each lead has
an exposed thick portion with an inner face and an outer face; and
an inner thin portion extending longitudinally from the exposed thick portion along the inner face and having a top face and a bottom face;
a chip mounted facedown on the leadframe, wherein the chip has a bottom surface, a top surface mounted on the leadframe and an I/O pad on the top surface facing the central opening and wire bonded to the bottom faces; and
encapsulant covers the chip and the leadframe except for the outer faces of the exposed thick portion, wherein the encapsulant has four sides.

2. The semiconductor package as claimed in claim 1, the leads of the leadframe are deposed in dual-lines to define two opposite edges of the central opening.

3. The semiconductor package as claimed in claim 1, the leads of the leadframe are deposed in quad-lines to define four opposite edges of the central opening.

4. The semiconductor package as claimed in claim 1, the inner thin portion of each lead is greater than half as thick as the exposed thick portion of the lead.

5. The semiconductor package as claimed in claim 1, the encapsulant covers the chip except for the bottom surface of the chip.

6. The semiconductor package as claimed in claim 1, where the exposed thick portions of the leads are flush with the sides of the encapsulant.

7. The semiconductor package as claimed in claim 1, where the exposed thick portions of leads protrude from the sides of the encapsulant.

8. The semiconductor package as claimed in claim 1, where silver is plated on the bottom face of each inner thin portion.

9. The semiconductor package as claimed in claim 1, an alloy of Ni, Pd and Au is plated the bottom face of each inner thin portion to securely attach the wires between the chip and the leads.
